(19) United States
(12) Patent Application Publication
(10) Pub. No.: US 2022/0209175 A1
(43) Pub. Date: Jun. 30, 2022

(54) OLED DISPLAY PANEL, METHOD OF FORMING DISPLAY PANEL AND DISPLAY DEVICE

(71) Applicant: BOE Technology Group Co., Ltd., Beijing (CN)

(72) Inventors: Xueyan TIAN, Beijing (CN); Liangjian LI, Beijing (CN)

(21) Appl. No.: 17/609,950

(22) PCT Filed: Feb. 2, 2021
(86) PCT No.: PCT/CN2021/074876

§ 371 Date: Nov. 9, 2021

(30) Foreign Application Priority Data
Mar. 31, 2020 (CN) 2020 10245700.2

(51) Int. Cl. H01L 51/52; H01L 51/56; H01L 27/32

(52) U.S. Cl. CPC H01L 51/5234; H01L 27/3267; H01L 51/5271; H01L 51/56

(57) ABSTRACT

An OLED display panel, a method of forming a display panel and a display device are provided. An OLED display panel, including a transparent base and a plurality of pixel repeating units arranged on the transparent base in an array distribution, where at least one of the pixel repeating units includes: a display function layer and a specular function layer between the display function layer and the transparent base; where the specular function layer includes a specular reflection area and a light-transmitting area; the display function layer includes a first pixel area and a second pixel area, the first pixel area is provided with a first OLED light-emitting unit, and the first OLED light-emitting unit is configured to emit light in a direction away from the transparent base; the second pixel area is provided with a second OLED light-emitting unit, the second OLED light-emitting unit is configured to emit light toward the transparent base, and the emitted light is able to pass through the light-transmitting area.

### CROSS-REFERENCE TO RELATED APPLICATION

This application claims a priority to Chinese Patent Application No. 202010245700.2 filed on Mar. 31, 2020, the disclosure of which is incorporated in its entirety by reference herein.

### TECHNICAL FIELD

The present disclosure relates to the field of display technology, in particular to an OLED display panel, a method of forming a display panel and a display device.

### BACKGROUND

With the development of display technology, consumers have increasingly diversified functional requirements for display devices. In addition to requiring display devices with fast response speed, high resolution, and fine image quality, they are also gradually pursuing breakthroughs in functions and display modes. Specular display has become one of the new display structures. It usually uses transflective film to achieve specular display effect. It can be applied to car rearview mirror, makeup mirror, etc. However, the existing specular display has a lower transmittance in the display area, and affected by the external reflected light, resulting in the problem of low contrast displayed on the specular display screen.

In addition, based on the current market demand, double-sided organic light-emitting diode (Organic Light Emitting Display, OLED) displays have emerged. In addition to the various characteristics of ordinary OLED displays, double-sided OLED displays can also extend the screen space, quickly switch and process Multiple display screens not only save the production cost of the display, but also save the space of the device. The existing double-sided OLED display screen structure usually includes two display panels for realizing display in two directions respectively, but this kind of display screen structure has the problems of high cost, difficulty in thinning the thickness, and relatively cumbersome.

Based on the above, realizing a thin and light double-sided OLED display at a lower cost and meeting the specular display effect has become the goal of current display development.

### SUMMARY

The present disclosure is to provide an OLED display panel, a method of forming a display panel, and a display device, which are configured to realize a light and thin double-sided OLED display at a lower cost, and can satisfy the specular display effect.

An OLED display panel is provided in an embodiment of the present disclosure, including a transparent base and a plurality of pixel repeating units arranged on the transparent base in an array distribution, where at least one of the pixel repeating units includes:

a display function layer and a specular function layer between the display function layer and the transparent base;

where the specular function layer includes a specular reflection area and a light-transmitting area;

the display function layer includes a first pixel area and a second pixel area, the first pixel area is provided with a first OLED light-emitting unit, and the first OLED light-emitting unit is configured to emit light in a direction away from the transparent base; the second pixel area is provided with a second OLED light-emitting unit, the second OLED light-emitting unit is configured to emit light toward the transparent base, and the emitted light is able to pass through the light-transmitting area.

Optionally, the second OLED light-emitting unit is further configured to emit light in a direction away from the transparent base.

Optionally, the first OLED light emitting unit includes a top-emission type OLED light emitting device, and the second OLED light emitting unit includes a bottom-emission type OLED light emitting device.

Optionally, the first OLED light-emitting unit includes a first anode, a first cathode and a first light-emitting layer between the first anode and the first cathode; the second OLED light-emitting unit includes a second anode, a second cathode and a second light-emitting layer between the second anode and the second cathode;

the first anode and the second anode, the first light-emitting layer and the second light-emitting layer, the first cathode and the second cathode are respectively arranged in a same layer, and the first cathode and the second anode are transparent electrodes.

Optionally, the second cathode is a transparent electrode.

Optionally, the first light-emitting layer is connected to the second light-emitting layer, and a color of the light emitted by the first light-emitting layer is the same as a color of the light emitted by second light-emitting layer.

Optionally, the display function layer further includes a first thin film transistor and a second thin film transistor, and the first thin film transistor is between the first OLED light-emitting unit and the specular function layer and configured to drive the first OLED light-emitting unit to emit light; the second thin film transistor is arranged between the second OLED light-emitting unit and the specular function layer and is configured to drive the second OLED light-emitting unit to emit light;

orthographic projections of the first thin film transistor and the second thin film transistor onto a plane where the specular function layer is located is within a range of the specular reflection area.

Optionally, the first thin film transistor includes a first active layer, a first gate, and a first source/drain, where the first source/drain is connected to the first anode of the first OLED light-emitting unit; the second thin film transistor includes a second active layer, a second gate and a second source/drain, the second source/drain is connected to the second anode of the second OLED light-emitting unit;

the first active layer and the second active layer, the first gate and the second gate, the first source/drain and the second source/drain are respectively arranged in a same layer.

Optionally, a metal reflective material is disposed on a part of region of a surface of the transparent base facing the display function layer, where the region of the surface of the transparent base disposed with the metal reflective material is the specular reflection area.

Optionally, the metal reflective material includes one of molybdenum MO, aluminum Al, Al alloy, titanium Ti, Ti alloy, Ti/Al/Ti laminated structure, silver Ag, Ag alloy and laminated structures of indium tin oxide ITO/Ag/ITO, or a combination of at least two of molybdenum MO, aluminum Al, Al alloy, titanium Ti, Ti alloy, Ti/Al/Ti laminated structure, silver Ag, Ag alloy and laminated structures of indium tin oxide ITO/Ag/ITO.

A display device is provided in an embodiment of the present disclosure, including the OLED display panel hereinabove.

A method of forming a display panel is provided in an embodiment of the present disclosure, where the display panel is the display panel hereinabove, and the method includes:

forming a transparent base;

forming a specular function layer including a specular reflection area and a light-transmitting area on the transparent base;

forming a display function layer on the specular function layer;

the display function layer includes a first pixel area and a second pixel area, the first pixel area is provided with a first OLED light-emitting unit, and the first OLED light-emitting unit is configured to emit light in a direction away from the transparent base; the second pixel area is provided with a second OLED light-emitting unit, the second OLED light-emitting unit is configured to emit light toward the transparent base, and the emitted light is able to pass through the light-transmitting area.

Optionally, the forming the specular function layer including the specular reflection area and the light-transmitting area on the transparent base includes:

depositing a metal reflective material on the transparent base;

patterning the metal reflective material to form a metal reflective material reserved area and a metal reflective material removed area, the metal reflective material reserved area is formed as the specular reflection area, and the metal reflective material removed area is formed as the light-transmitting area.

Optionally, the first OLED light-emitting unit includes a first anode, a first cathode and a first light-emitting layer between the first anode and the first cathode; the second OLED light-emitting unit includes a second anode, a second cathode and a second light-emitting layer between the second anode and the second cathode, the forming the display function layer on the specular function layer includes:

forming the first anode and the second anode through two patterning processes;

forming the first light-emitting layer and the second light-emitting layer through one evaporation process; and

forming the first cathode and the second cathode of the same material through the same vapor deposition process, or forming the first cathode and the second cathode of different materials through different vapor deposition processes.

### BRIEF DESCRIPTION OF THE DRAWINGS

In order to explain the technical solutions of the embodiments of the present disclosure more clearly, the following will briefly introduce the accompanying drawings used in the description of the embodiments of the present disclosure. Obviously, the accompanying drawings in the following description are only some embodiments of the present disclosure. For those of ordinary skill in the art, without creative labor, other drawings can be obtained based on these drawings.

FIG. 1 is a schematic view of a cross-sectional structure of an OLED display panel according to an embodiment of the present disclosure;

FIG. 2 is a schematic view of a planar structure of a first display surface in an OLED display panel according to an embodiment of the present disclosure;

FIG. 3 is a schematic view of a planar structure of a second display surface in an OLED display panel according to an embodiment of the present disclosure;

FIG. 4 is a schematic view of a cross-sectional structure of an OLED display panel according to an embodiment of the present disclosure;

FIG. 5 is a schematic flowchart of a method of forming an OLED display panel according to an embodiment of the present disclosure; and

FIGS. 6 to 34 are schematic flowchart of a process of a method of forming a display panel according to an embodiment of the present disclosure.

### DETAILED DESCRIPTION

In order to make the technical problems, technical solutions and advantages to be solved by the present disclosure clearer, a detailed description will be given below in conjunction with the accompanying drawings and specific embodiments.

The embodiment of the present disclosure provides an OLED display panel, on a transparent base, a specular function layer is formed between the display function layer and the transparent base, and the specular function layer includes a specular reflection area and a light-transmitting area, and the display function layer includes a first OLED light-emitting unit that emits light in the direction facing away of the transparent base, thereby realizing image display on the first display surface of the OLED display panel, and the OLED display panel further includes a second OLED light-emitting unit that emits light in the direction toward the transparent base, and the emitted light can pass through the light-transmitting area of the specular function layer to realize the image display on the second display surface of the OLED display panel; in addition, the specular reflection area of the specular function layer is configured to realize the specular display effect on the second display surface of the OLED display panel. Therefore, the OLED display panel according to the embodiment of the present disclosure can realize double-sided display and can satisfy the specular display effect.

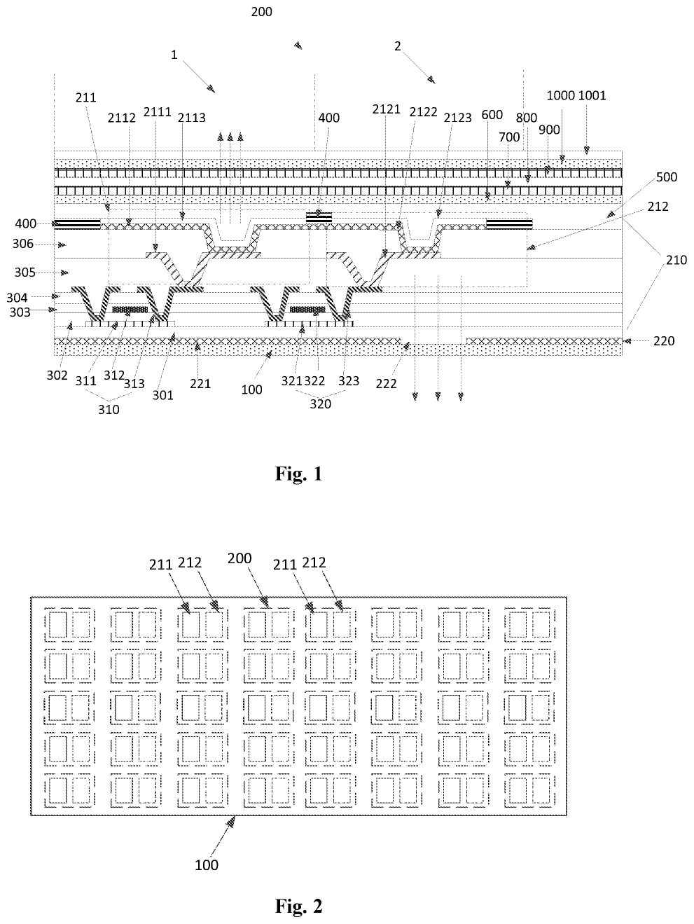

Specifically, as shown in FIG. 1, the OLED display panel according to one embodiment of the present disclosure includes a transparent base 100 and a plurality of pixel repeating units 200 arranged on the transparent base 100 and arranged in an array form, where at least one pixel repeating unit 200 includes:

a display function layer 210 and a specular function layer 220 between the display function layer 210 and the transparent base 100;

the specular function layer 220 includes a specular reflection area 221 and a light-transmitting area 222;

the display function layer 210 includes a first pixel area 1 and a second pixel area 2, the first pixel area 1 is provided with a first OLED light-emitting unit 211, and the first OLED light-emitting unit 211 is configured to emit light in a direction away from the transparent base; the second pixel area 2 is provided with a second OLED light-emitting unit 212, the second OLED light-emitting unit 212 is configured to emit light toward the transparent base 100, and the emitted light is able to pass through the light-transmitting area 222.

According to the OLED display panel in the embodiment, the first OLED light-emitting unit and the second OLED light-emitting unit that can emit light in two different directions are formed on the transparent base 100, and a single display panel can be configured to achieve a light and thin double-sided OLED display at a lower cost. In addition, the specular display is integrated on the double-sided display to meet the specular display effect of double-sided display.

Optionally, in the OLED display panel, each pixel repeating unit 200 includes the display function layer 210 and the specular function layer 220 described above.

In the embodiment of the present disclosure, optionally, in each pixel repeating unit 200, a first OLED light-emitting unit 211 and a second OLED light-emitting unit 212 are respectively provided. Correspondingly, in one pixel repeating unit 200, the corresponding specular function layer 220 includes a specular reflection area 221 and a light-transmitting area 222.

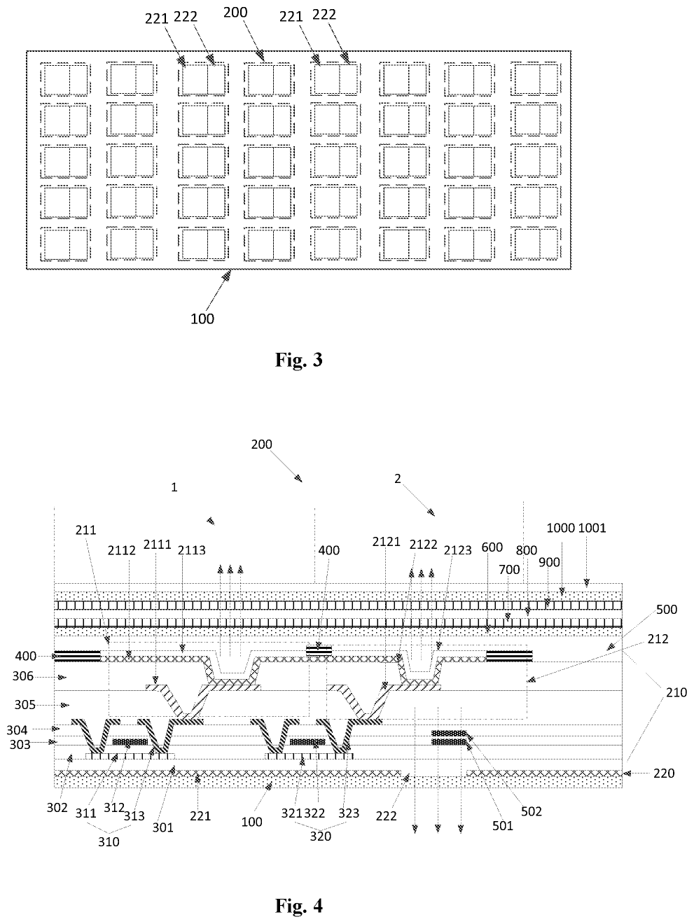

FIG. 2 is a schematic view of a planar structure of a first display surface in an OLED display panel according to an embodiment of the present disclosure; FIG. 3 is a schematic view of a planar structure of a second display surface.

In the embodiment of the present disclosure, optionally, on the first display surface of the OLED display panel, N×M pixel repeating units 200 are sequentially arranged, and each pixel repeating unit 200 includes a first OLED light-emitting unit 211, where Each first OLED light-emitting unit 211 may correspond to one of a red sub-pixel, a green sub-pixel, and a blue sub-pixel. With a plurality of first OLED light-emitting units 211, the OLED display panel can display an image on the first display surface.

Optionally, on the second display surface of the OLED display panel, as shown in FIG. 3, N×M pixel repeating units 200 are arranged in sequence, and each pixel repeating unit 200 includes a specular reflection area 221 and a light-transmitting area. In the area 222, a light-transmitting area 222 corresponds to a second OLED light-emitting unit 212, and the light emitted by the corresponding second OLED light-emitting unit 212 can be transmitted through the light-transmitting area 222. Each second OLED light-emitting unit 212 can correspond to one of red sub-pixel, green sub-pixel, and blue sub-pixel. With multiple second OLED light-emitting units 212, the OLED display panel can display the image on the second display surface. In addition, by using the specular reflection area 221 of the multiple pixel repeating units 200, the specular reflection display can also be realized on the second display surface.

It should be noted that, on the first display surface of the OLED display panel, one pixel repeating unit 200 includes a first OLED light-emitting unit 211, and on the second display surface of the OLED display panel, one pixel repeating unit 200 includes a specular reflection area. 221 and a light-transmitting area 222 are only examples, and the details are not limited thereto. For example, a pixel repeating unit 200 may include two spaced first OLED light-emitting units 211, or include two spaced light-transmitting regions 222, etc., which are not illustrated one by one here, and can be specifically set according to the display screen requirements of the display panel.

In the embodiment of the present disclosure, in the OLED display panel of the embodiment shown in FIG. 1, optionally, the first OLED light-emitting unit 211 includes a top-emission OLED light-emitting device, and the second OLED light-emitting unit 212 includes a bottom-emission OLED light-emitting device.

It should be noted that the OLED light-emitting unit includes an anode, a cathode, and a light-emitting layer between the anode and the cathode, which are arranged oppositely. The light-emitting layer includes a hole-injection layer, a hole-transport layer, a light emitting layer, an electron transport layer and an electron injection layer. Using the difference between the anode and the cathode, the light-emitting layer can emit light. In the embodiment of the present disclosure, the anode and cathode in the OLED light-emitting unit are made of light-transmitting materials or light-reflecting materials, and the direction of light emitted by the light-emitting layer is controlled to realize image display on both sides of the OLED display panel.

As shown in FIG. 1, the first OLED light-emitting unit 211 includes a top-emission OLED light-emitting device. Specifically, from a direction close to the transparent base 100 to a direction away from the transparent base 100, the first OLED light-emitting unit 211 includes first anode 2111, the first light-emitting layer 2112 and the first cathode 2113; where the first anode 2111 is made of a reflective anode material, such as a laminate material of indium tin oxide ITO/silver Ag/ITO, and the first cathode 2113 is made of light-transmitting cathode material, that is, the first cathode 2113 is a transparent electrode. For example, the made material includes at least one of magnesium Mg and Ag materials to form a top-emission OLED light-emitting device for emitting light in a direction away from the transparent base 100, to realize the image display on the first display surface as shown in FIG. 2.

The second OLED light-emitting unit 212 includes a second anode 2121, a second light-emitting layer 2122, and a second cathode 2123 arranged in sequence; where, the second anode 2121 is made of a highly transparent anode material, that is, the second anode 2121 is transparent The electrode is made of ITO; the second cathode 2123 is made of a highly reflective cathode material, such as Al, which is formed as a bottom-emission OLED light-emitting device for emitting light toward the transparent base 100 to achieve the image display on the second display surface shown in FIG. 3.

Optionally, in this embodiment of the present disclosure, the orthographic projection of the first anode 2111 on a plane where the specular function layer 220 is located is in the area where the specular reflection area 221 is located.

Optionally, in order to ensure the display brightness of the second display surface, the first OLED light-emitting unit 211 includes a top-emission OLED light-emitting device.

However, it should be noted that when the orthographic projection of the first anode 2111 on the plane where the specular function layer 220 is located is in the area where the specular reflection area 221 is located, the first anode 2111 is not limited to being made of only reflective anode materials. It can be made of a light-transmitting material, and the use of the specular reflection area 221 can also ensure that the light emitted by the first OLED light-emitting unit 211 will not pass through the second display surface of the OLED display panel. The OLED display panel according to another embodiment of the present disclosure, as shown in FIG. 4, is the same as the embodiment shown in Fig. The specular-surface function layer 220 in between; the specular-surface function layer 220 includes a specular reflection area 221 and a light-transmitting area 222. The display function layer 210 includes a first pixel area 1 and a second pixel area 2. The first pixel area 1 is provided with a first OLED light emitting unit 211, and the second pixel area 2 is provided with a second OLED light emitting unit 212.

In this embodiment, the first OLED light-emitting unit 211 is configured to emit light in a direction away from the transparent base 100; the second OLED light-emitting unit 212 is configured to emit light in a direction toward the transparent base 100, and the emitted light can pass through the light-transmitting area 222, it is also configured to emit light in a direction away from the transparent base 100.

According to this embodiment, as shown in FIG. 2, on the first display surface of the OLED display panel, N×M pixel repeating units 200 are arranged in sequence, and each pixel repeating unit 200 includes a first OLED light-emitting unit 211 and One second OLED light-emitting unit 212, where each first OLED light-emitting unit 211 may correspond to one of a red sub-pixel, a green sub-pixel, and a blue sub-pixel, and each second OLED light-emitting unit 212 corresponds to one of a red sub-pixel, a green sub-pixel and a blue sub-pixel; through the plurality of first OLED light-emitting units 211 and the plurality of second OLED light-emitting units 212, the OLED display panel can display images on the first display surface.

As shown in FIG. 3, on the second display surface of the OLED display panel, N×M pixel repeating units 200 are arranged in sequence, and a light-transmitting area 222 corresponds to a second OLED light-emitting unit 212. Through the light-transmitting area 222, the light emitted by the corresponding second OLED light-emitting unit 212 can be transmitted through. Through the plurality of second OLED light emitting units 212, the OLED display panel can display images on the second display surface. In addition, by using the specular reflection area 221 of the multiple pixel repeating units 200, the specular reflection display can also be realized on the second display surface.

In this embodiment, optionally, the first anode 2111 of the first OLED light-emitting unit 211 is made of a reflective anode material, such as a laminated material of indium tin oxide ITO/silver Ag/ITO, and the first cathode 2113 is made of a light-transmitting anode material, such as including at least one of magnesium Mg and Ag materials, formed into a top-emission OLED light-emitting device; the second anode 2121 of the second OLED light-emitting unit 212 is made of a highly light-transmitting anode material, such as ITO; at the same time, the second cathode 2123 is made of a highly transparent cathode material, such as at least one of magnesium Mg and Ag materials, that is, the second anode 2121 and the second cathode 2123 are both transparent electrodes.

Using the OLED display panel described in the embodiment of FIG. 4, compared to the OLED display panel described in the embodiment of FIG. 1, both the first OLED light-emitting unit 211 and the second OLED light-emitting unit 212 can be used for the first display of the OLED display panel. The display of the image on the surface can achieve the effect of increasing the resolution of the image displayed on the first display surface.

Further, in the OLED display panel according to the embodiment of the present disclosure, as shown in FIG. 1 and FIG. 4, in the OLED display panel, on the surface of the transparent base 100 facing the display function layer 210, a metal reflective material is deposited in a part of the area, the area where the metal reflective material is deposited is formed as the specular reflection area 221, and the area where the metal reflective material is not deposited is formed as the light-transmitting area 222.

In addition, as shown in FIGS. 1 and 4, the display function layer 210 further includes a first thin film transistor 310 and a second thin film transistor 320. The first thin film transistor 310 is between the first OLED light-emitting unit 211 and the specular function layer 220. Used to drive the first OLED light-emitting unit 211 to emit light; the second thin film transistor 320 is between the second OLED light-emitting unit 212 and the specular function layer 220, and is configured to drive the second OLED light-emitting unit 212 to emit light;

The orthographic projection of the first thin film transistor 310 and the second thin film transistor 320 on the plane where the specular function layer 220 is located is within the range where the specular reflection area 221 is located.

Further, as shown in FIGS. 1 and 4, the first thin film transistor 310 includes a first active layer 311, a first gate 312, and a first source/drain 313, where the first source/drain 313 and the first anode 2111 connection; the second thin film transistor 320 includes a second active layer 321, a second gate 322 and a second source/drain 323, and the second source/drain 323 is connected to the second anode 2121.

The first active layer 311 and the second active layer 321, the first gate 312 and the second gate 322, the first source/drain 313 and the second source/drain 323 are respectively arranged in the same layer.

In the embodiment of the present disclosure, optionally, as shown in FIGS. 1 and 4, in the first OLED light emitting unit 211 and the second OLED light emitting unit 212, the first anode 2111 and the second anode 2121, the first light emitting layer 2112 and the second light-emitting layer 2122, the first cathode 2113 and the second cathode 2123, are arranged in the same layer respectively. The above-mentioned layers of the first OLED light-emitting unit 211 and the second OLED light-emitting unit 212 are arranged in the same layer to simplify the manufacturing process of the OLED display panel and make the OLED display panel lighter and thinner.

In the embodiment of the present disclosure, optionally, in the same pixel repeating unit 200, the first light-emitting layer 2112 of the first OLED light-emitting unit 211 is connected to the second light-emitting layer 2122 of the second OLED light-emitting unit 212, and is configured to emit light of the same color, that is, the first OLED light-emitting unit 211 and the second light-emitting unit 212 correspond to sub-pixels of the same color.

Optionally, a spacer PS layer 400 is provided at the connection position of the first light-emitting layer 2112 and the second light-emitting layer 2122 on the side away from the transparent base 100 for separating the first OLED light-emitting unit 211 and the second light-emitting unit 211.

With reference to FIG. 1 and FIG. 4, the OLED display panel according to the embodiment of the present disclosure is specifically:

The surface of the transparent base 100 facing the display function layer 210 is provided with a specular function layer 220, and the specular function layer 220 includes a specular reflection area 221.

A display function layer 210 is provided on the specular reflection area 221, where the display function layer 210 includes a first thin film transistor 310 and a second thin film transistor 320, and also includes a buffer layer 301 formed on the specular function layer 220, where the first active layer 311 of the first film transistor 310 and the second active layer 321 of the second thin film transistor 320 are formed on the buffer layer 301.

The display function layer 210 further includes a first gate insulating layer 302 formed on the buffer layer 301, where the first gate 312 of the first thin film transistor 310 and the second gate 322 of the second thin film transistor 320 are formed on the first gate insulating layer 302.

The display function layer 210 also includes a second gate insulating layer 303 formed on the first gate insulating layer 302. As shown in FIG. 4, an electrode plate 501, and a second electrode plate 502 opposite to the first electrode plate 501 can be formed on the second gate insulating layer 303 to form a storage capacitor.

Further, the display function layer 210 further includes an interlayer insulating layer 304 formed on the second insulating layer 303, where the first source/drain 313 of the first thin film transistor 310 and the second source/drain electrode 323 of the second thin film transistor 320 are formed on the interlayer insulating layer 304, and the first source/drain electrode 313 is connected to the first active layer 311 through a via hole penetrating the interlayer insulating layer 304, the second gate insulating layer 303 and the first gate insulating layer 302; the second source/drain 323 is connected to the second active layer 321 through via hole penetrating the interlayer insulating layer 304, the second gate insulating layer 303, and the first gate insulating layer 302;

In addition, according to FIGS. 1 and 4, the display function layer 210 further includes a planarization layer 305 formed on the interlayer insulating layer 304, where the first anode 2111 and the second anode 2121 are formed on the planarization layer 305, the first anode 2111 penetrates the via hole of the planarization layer 305 to connect to the first source/drain 313, and a second anode 2121 penetrates the via hole of the planarization layer 305 to connect to the second source/drain 323.

Further, a pixel defining layer 306 is formed on the planarization layer 305, where the first light-emitting layer 2112 and the second light-emitting layer 2122 are formed on the pixel defining layer 306, and the first light-emitting layer 2112 penetrates the via hole in the pixel defining layer 306 to connect to the first anode 2111, and the second light-emitting layer 2122 penetrates the via hole in the pixel defining layer 306 to connect to the second anode 2121.

Based on the above structure, the first cathode 2113 is formed on the first light-emitting layer 2112, the second cathode 2123 is formed on the second light-emitting layer 2122, and a spacer PS is arranged between the first cathode 2113 and the second cathode 2123 The layer 400 is configured to separate the first OLED light-emitting unit 211 and the second OLED light-emitting unit 212 in the same pixel repeating unit 200; in addition, on the pixel defining layer 306, a portion of the first light-emitting layer 2112 away from the second light-emitting layer 2122 The side of the second light-emitting layer 2122, and the side of the second light-emitting layer 2122 away from the first light-emitting layer 2112, are also respectively formed with a spacer PS layer 400 for separating different pixel repeating units 200;

In the embodiment of the present disclosure, optionally, as shown in FIG. 1 and FIG. 4, the OLED display panel further includes an encapsulation layer TFE 500, a pressure-sensitive adhesive PSA 600, a circle polarizer CPOL 700, first optical adhesive layer OCA 800, a touch layer 900, a second optical adhesive layer OCA 1000, and a glass cover 1001 formed on the first cathode 2113 and the second cathode 2123 in sequence.

The OLED display panel according to the embodiment of the present disclosure can use one display panel to realize double-sided OLED display. In addition, the specular display is integrated on the double-sided display, which can meet the specular display effect of double-sided display. Compared with the single-sided OLED display panel in the related art,

by adding the specular reflection area 221 of the specular function layer 220 on the transparent base 100, and by forming the first anode and the second anode made of different materials by using the mask twice when the anode is formed, the double-sided OLED display panel described in the embodiment of the present disclosure can be formed, therefore a lighter and thinner double-sided OLED display can be realized at a lower cost.

Optionally, in conjunction with FIG. 1 and FIG. 4, in the OLED display panel according to the embodiment of the present disclosure, when the first OLED light-emitting unit 211 and the second OLED light-emitting unit 212 are connected to the circuit, independent VDD may be used for control, respectively. By separately adjusting the voltage on the VDD line, the brightness of the corresponding light-emitting unit can be improved. Further, the first OLED light-emitting unit 211 and the second OLED light-emitting unit 212 can also independently adjust the Gamma curve, respectively, by adjusting the voltage of the data lines on the first OLED light-emitting unit 211 and the second OLED light-emitting unit 212 to increase and balance each brightness of the display surface.

It should be noted that, in the embodiment of the present disclosure, the types of the first thin film transistor 310 and the second thin film transistor 320 are not limited, and can be formed by using Low Temperature Poly-silicon-Thin Film Transistor (LTPS-TFT). Indium gallium zinc oxide-Thin Film Transistor (IGZO-TFT) can also be used, or the two can be combined with each other.

In addition, the specific implementation structure of the OLED display panel described in the foregoing embodiment is not limited to those shown in FIG. 1 and FIG. The structure principle should be able to be made into OLED display panels with other implementation structures, which will not be described in detail here.

In another aspect, the embodiments of the present disclosure also provide a display device, which includes an OLED panel with the above-implemented structure.

With reference to FIGS. 1 to 4 and based on the above detailed description, those skilled in the art should be able to understand the specific structure of the display device using the OLED display panel according to the embodiment of the present disclosure, which will not be described in detail here.

It should be noted that, in the display device according to the embodiment of the present disclosure, the OLED display panel may be a rigid active-matrix organic light-emitting diode (AMOLED) display panel, or it may be a flexible AMOLED display panel. The panel, that is, the transparent base, can be made of a glass substrate, or can be made of a flexible PI substrate.

The display device may be any one of a foldable mobile phone, a notebook computer, an e-book, a tablet computer, and a display glass wall.

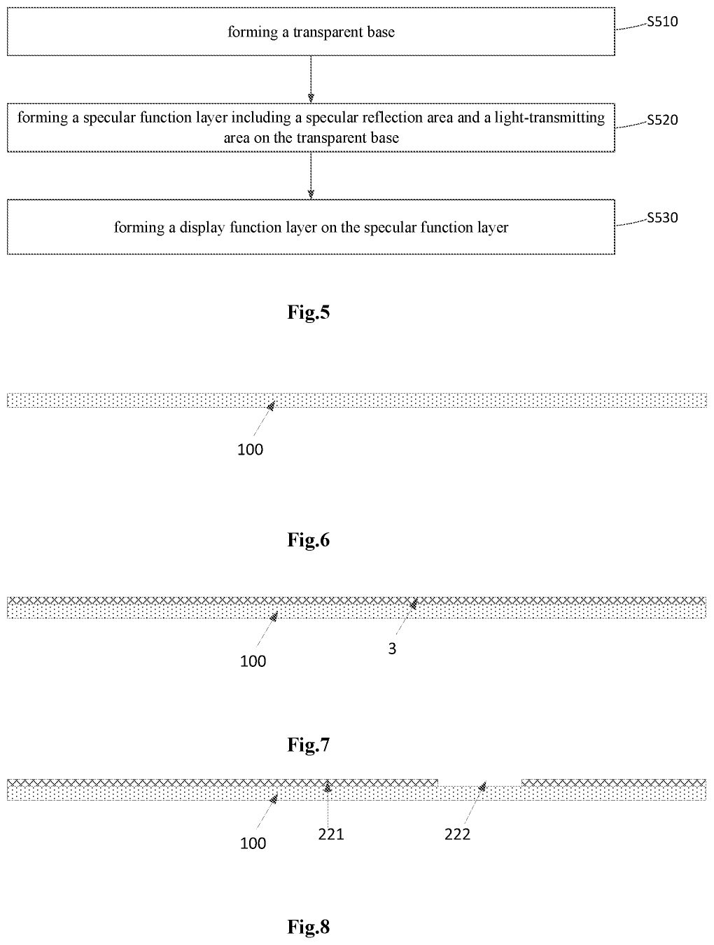

In another aspect, the embodiments of the present disclosure also provide a method for forming a display panel. The display panel is the display panel described in any one of the above items. As shown in FIG. 5, the method includes:

S510: forming a transparent base;

S520: forming a specular function layer including a specular reflection area and a light-transmitting area on the transparent base;

S530: forming a display function layer on the specular function layer;

the display function layer includes a first pixel area and a second pixel area, the first pixel area is provided with a first OLED light-emitting unit, and the first OLED light-emitting unit is configured to emit light in a direction away from the transparent base; the second pixel area is provided with a second OLED light-emitting unit, the second OLED light-emitting unit is configured to emit light toward the transparent base, and the emitted light is able to pass through the light-transmitting area.

In step S520, the forming the specular function layer including the specular reflection area and the light-transmitting area on the transparent base includes:

depositing a metal reflective material on the transparent base;

patterning the metal reflective material to form a metal reflective material reserved area and a metal reflective material removed area, the metal reflective material reserved area is formed as the specular reflection area, and the metal reflective material removed area is formed as the light-transmitting area.

Optionally, the first OLED light-emitting unit includes a first anode, a first cathode and a first light-emitting layer between the first anode and the first cathode; the second OLED light-emitting unit includes a second anode, a second cathode and a second light-emitting layer between the second anode and the second cathode, the forming the display function layer on the specular function layer includes:

forming the first anode and the second anode through two patterning processes;

forming the first light-emitting layer and the second light-emitting layer through one evaporation process; and

forming the first cathode and the second cathode of the same material through the same vapor deposition process, or forming the first cathode and the second cathode of different materials through different vapor deposition processes.

Specifically, referring to FIGS. 6 to 34 and in conjunction with FIGS. 1 to 4, the manufacturing process of the OLED display panel according to the embodiment of the present disclosure includes the following steps:

forming a transparent base 100, as shown in FIG. 6, optionally, the transparent base 100 is one of a glass substrate and a flexible substrate;

depositing a metal reflective material 3 on the transparent base 100, as shown in FIG. 7, where the metal reflective material 3 includes molybdenum MO, aluminum Al, Al alloy, titanium Ti, Ti alloy, Ti/Al/Ti laminated structure, silver Ag, Ag alloy and indium tin oxide ITO/Ag/ITO laminated structure one of them, or a combination of at least two materials;

pattering a metal reflective material 3 to form a metal reflective material reserved area and a metal reflective material removed area, wherein the metal reflective material reserved area is formed as a specular reflection area 221, and the metal reflective material removed area is formed as a light-transmitting area 222, as shown in FIG. 8 Shown

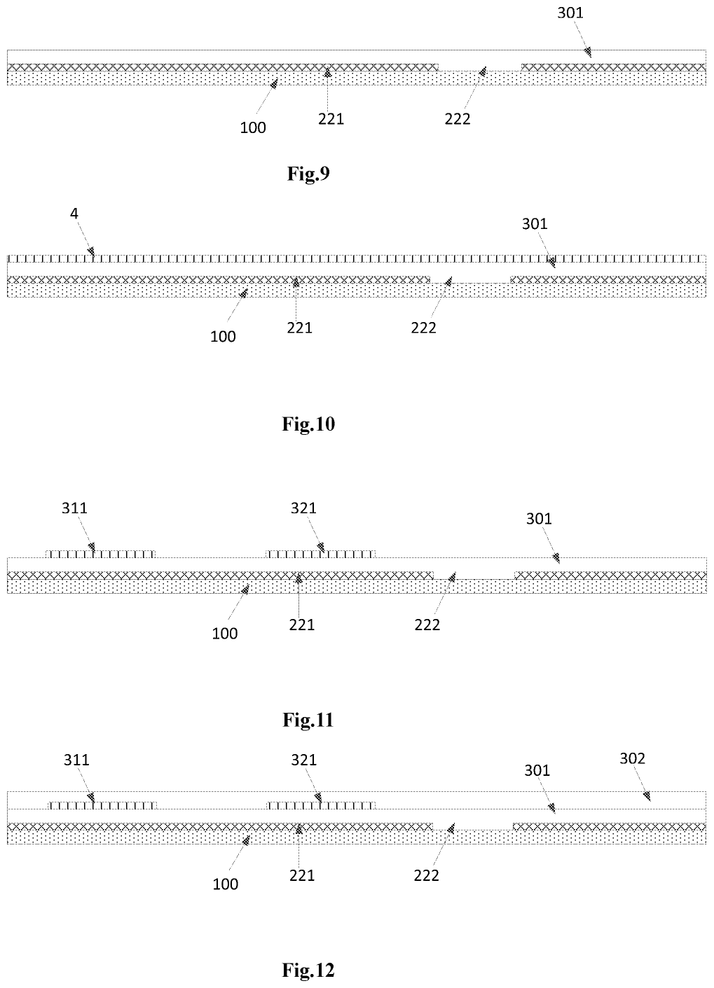

depositing a buffer layer 301 on the transparent base 100 made of the specular reflection area 221, as shown in FIG. 9;

depositing an active layer material 4 on the buffer layer 301, such as a P—Si material, as shown in FIG. 10;

pattering the active layer material 4, where the reserved areas are the first active layer 311 and the second active layer 321, as shown in FIG. 11;

depositing a gate insulating material layer on the buffer layer 301 on which the first active layer 311 and the second active layer 321 are formed to form the first gate insulating layer 302, as shown in FIG. 12;

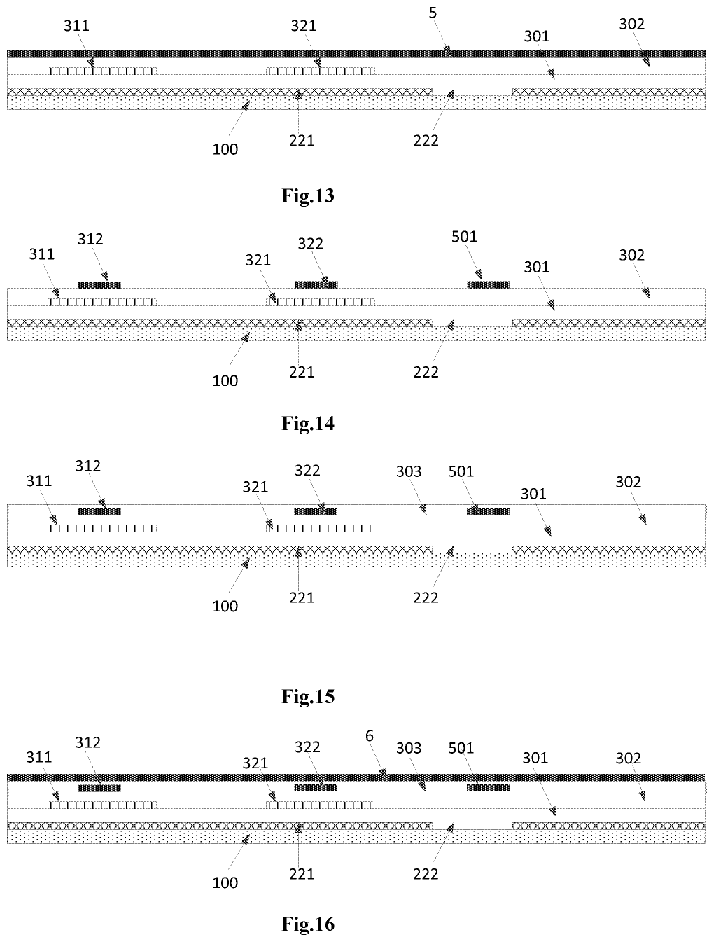

depositing a first gate material 5 on the first gate insulating layer 302, as shown in FIG. 13;

patterning first gate material 5, where the reserved areas formed are the first gate 312, the second gate 322 and the first plate 501 of the storage capacitor, as shown in FIG. 14;

depositing a gate insulating material on the first gate insulating layer 302 on which the first gate 312, the second gate 322 and the first electrode plate 501 are formed to form a second gate insulating layer 303, as shown in FIG. 15;

depositing a second gate material 6 on the second gate insulating layer 303, as shown in FIG. 16;

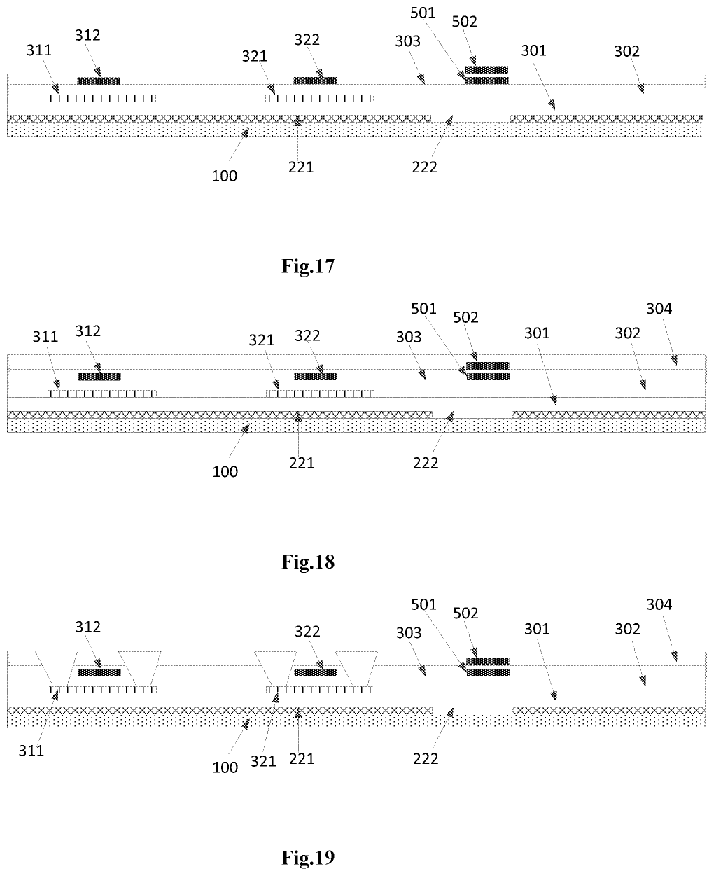

patterning the second gate material 6, where the reserved area formed is the second electrode plate 502, which is opposite to the first electrode plate 501, as shown in FIG. 17;

depositing an insulating layer material on the second gate insulating layer 303 on which the second electrode plate 502 is formed to form an interlayer insulating layer 304, as shown in FIG. 18;

forming the via by a patterning process, so that the via penetrates the interlayer insulating layer 304, the interlayer insulating layer 304, the second gate insulating layer 303, and the first gate insulating layer 302, and connects to the first active layer 311 and the second active layer, as shown in FIG. 19;

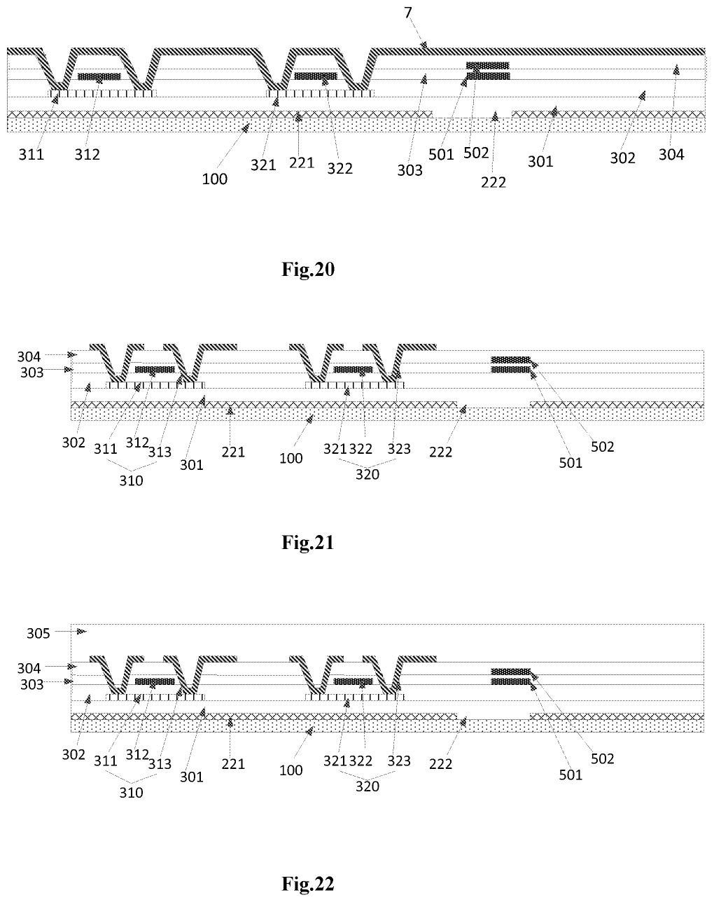

depositing the data line material 7 on the interlayer insulating layer 304, where the data line material 7 is connected to the first active layer 311 and the second active layer 321 through via holes, as shown in FIG. 20;

patterning the data line material 7, wherein the reserved regions formed are the first source/drain 313 and the second source/drain 323, as shown in FIG. 21;

depositing a planarization layer material on the interlayer insulating layer 304 on which the first source/drain 313 and the second source/drain 323 are formed to form a planarization layer 305, as shown in FIG. 22;

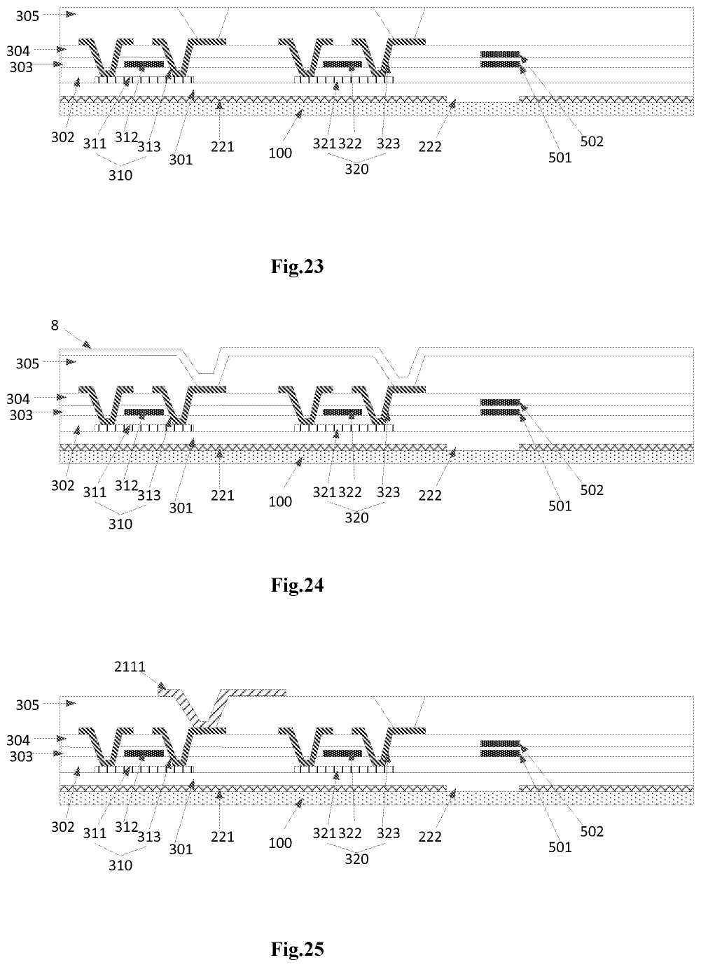

forming the via hole by a patterning process, so that the via penetrates the planarization layer 305 and is connected to the first source/drain 313 and the second source/drain 323, as shown in FIG. 23;

depositing a first anode material 8 with light-reflecting properties on the planarization layer 305, such as a laminated material of indium tin oxide ITO/silver Ag/ITO, as shown in FIG. 24;

patterning the first anode material 8, where the formed reserved area is the first anode 2111, which is connected to the first source/drain 313, as shown in FIG. 25;

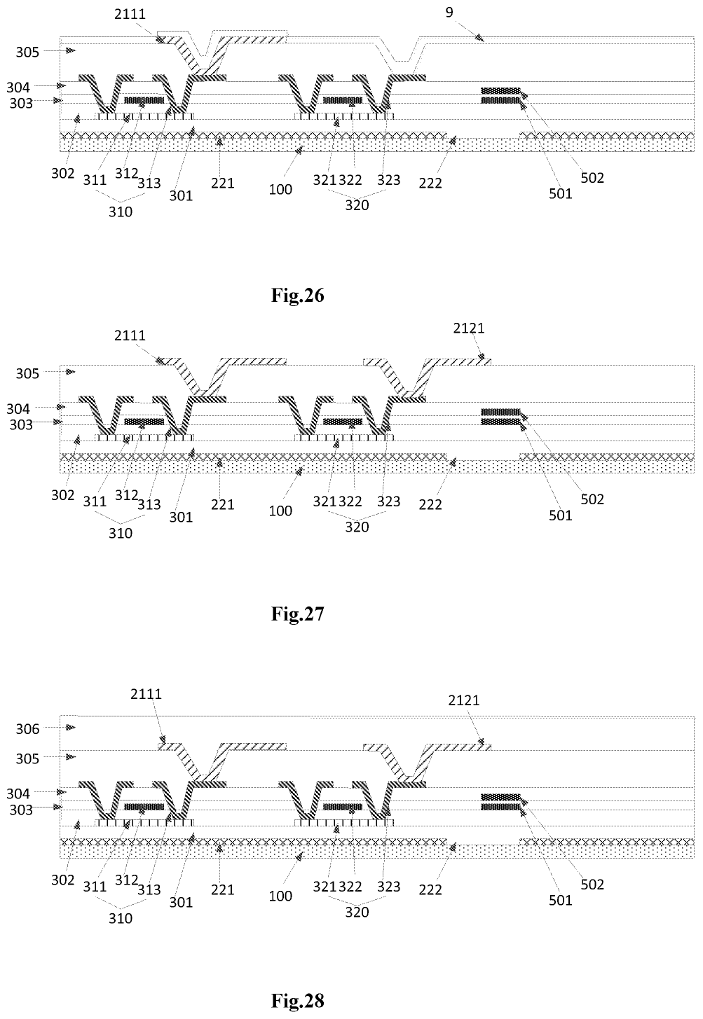

depositing a second anode material 9 with high light transmittance, such as ITO, on the planarization layer 305 with the first anode 2111, as shown in FIG. 26;

patterning the second anode material, and the formed reserved area is the second anode 2121, which is connected to the second source/drain 323, as shown in FIG. 27;

depositing the pixel defining layer material on the planarization layer 305 made of the first anode 2111 and the second anode 2121 to form the pixel defining layer 306, as shown in FIG. 28;

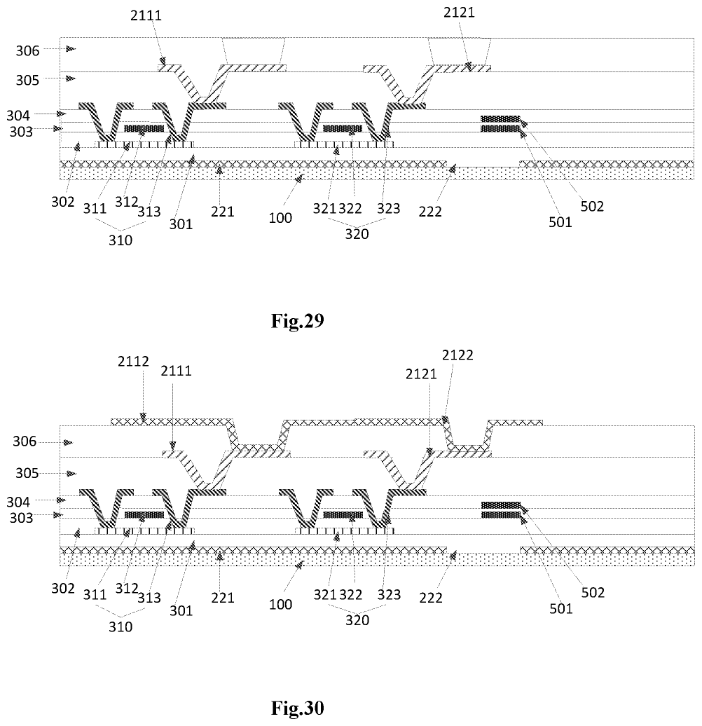

forming a via hole by a patterning process, so that the via hole penetrates the pixel defining layer 306 and is connected to the first anode 2111 and the second anode 2121, as shown in FIG. 29;

forming the first light-emitting layer 2112 and the second light-emitting layer 2122 through the same evaporation process, as shown in FIG. 30;

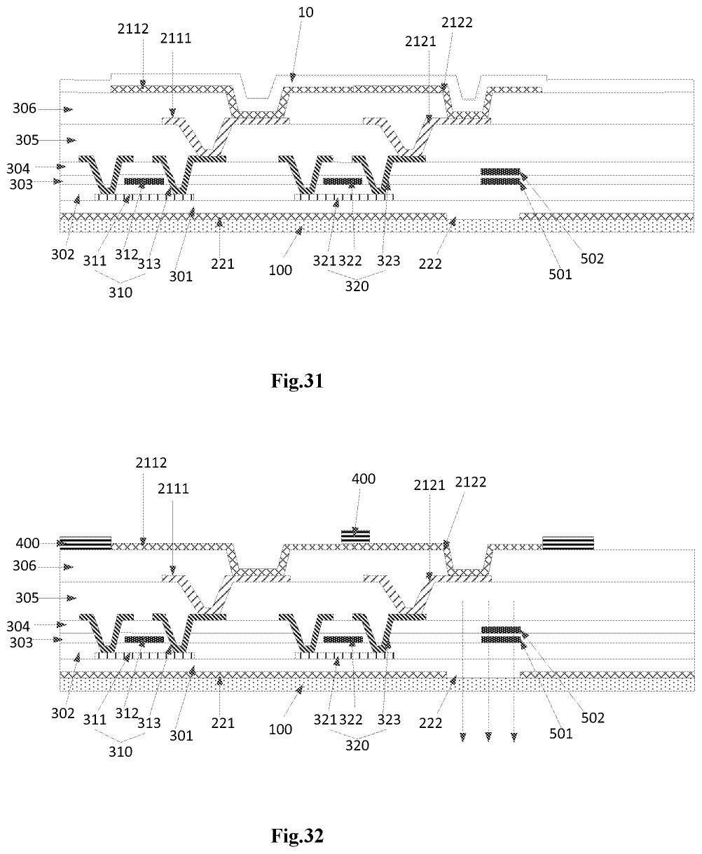

depositing the spacer layer material 10 on the pixel defining layer 306 with the first light-emitting layer 2112 and the second light-emitting layer 2122, as shown in FIG. 31;

patterning the spacer layer material 10, where the formed reserved area is formed as a spacer PS layer 400, as shown in FIG. 32;

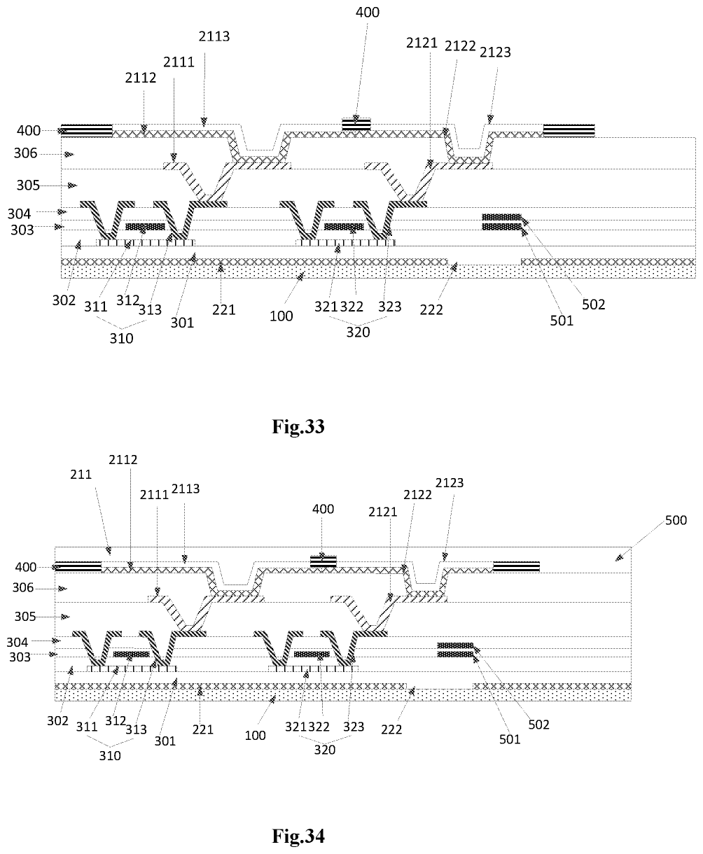

on the basis of making the spacer layer 400, when the first cathode 2113 and the second cathode 2123 are both light-transmitting, as shown in FIG. 4, the first cathode 2113 and the second cathode 2123 are formed through a single evaporation process. As shown in FIG. 33; when the first cathode 2113 is light-transmitting and the second cathode 2123 is opaque, as shown in FIG. 1, the first cathode 2113 and the second cathode 2123 can be formed through two evaporation processes;

depositing an encapsulation material on the manufactured first cathode 2113 and second cathode 2123 to form an encapsulation layer 500, as shown in FIG. 34.

On this basis, it can be understood that the production of the OLED display panel also includes the sequential production of PSA 600, CPOL 700, first optical adhesive layer OCA 800, touch layer 900, and second optical adhesive layer on the encapsulation layer 500. The process of OCA 1000 and glass cover 1001 will not be described in detail here separately.

According to the method of forming the OLED display panel according to the embodiment of the present disclosure, compared with the forming method of the OLED display panel in the related art, the forming process of the specular reflection area 221 of the specular function layer 220 is added on the transparent base 100, and the anode is manufactured. At the same time, the first anode and the second anode of different materials are formed through the mask process twice, that is, the double-sided OLED display panel described in the embodiment of the present disclosure can be formed, and therefore, a lightweight and thin dual Surface OLED display.

The above are some embodiments of the present disclosure. It should be pointed out that for those of ordinary skill in the art, without departing from the principle of the present disclosure, several improvements and modifications can be made, and these improvements and modifications should also be considered to be the scope of the present disclosure.

1. An OLED display panel, comprising a transparent base and a plurality of pixel repeating units arranged on the transparent base in an array distribution, wherein at least one of the pixel repeating units comprises:
a display function layer and a specular function layer between the display function layer and the transparent base;
wherein the specular function layer comprises a specular reflection area and a light-transmitting area;
the display function layer comprises a first pixel area and a second pixel area, the first pixel area is provided with a first OLED light-emitting unit, and the first OLED light-emitting unit is configured to emit light in a direction away from the transparent base; the second pixel area is provided with a second OLED light-emitting unit, the second OLED light-emitting unit is configured to emit light toward the transparent base, and the emitted light is able to pass through the light-transmitting area.

2. The OLED display panel according to claim 1, wherein the second OLED light-emitting unit is further configured to emit light in a direction away from the transparent base.

3. The OLED display panel according to claim 1, wherein the first OLED light emitting unit comprises a top-emission type OLED light emitting device, and the second OLED light emitting unit comprises a bottom-emission type OLED light emitting device.

4. The OLED display panel according to claim 1, wherein the first OLED light-emitting unit comprises a first anode, a first cathode and a first light-emitting layer between the first anode and the first cathode; the second OLED light-emitting unit comprises a second anode, a second cathode and a second light-emitting layer between the second anode and the second cathode;
the first anode and the second anode, the first light-emitting layer and the second light-emitting layer, the first cathode and the second cathode are respectively arranged in a same layer, and the first cathode and the second anode are transparent electrodes.

5. The OLED display panel according to claim 4, wherein the second cathode is a transparent electrode.

6. The OLED display panel according to claim 4, wherein the first light-emitting layer is connected to the second light-emitting layer, and a color of the light emitted by the first light-emitting layer is the same as a color of the light emitted by second light-emitting layer.

7. The OLED display panel according to claim 1, wherein the display function layer further comprises a first thin film transistor and a second thin film transistor, and the first thin film transistor is between the first OLED light-emitting unit and the specular function layer and configured to drive the first OLED light-emitting unit to emit light; the second thin film transistor is arranged between the second OLED light-emitting unit and the specular function layer and is configured to drive the second OLED light-emitting unit to emit light;
orthographic projections of the first thin film transistor and the second thin film transistor onto a plane where the specular function layer is located is within a range of the specular reflection area.

8. The OLED display panel according to claim 7, wherein the first thin film transistor comprises a first active layer, a first gate, and a first source/drain, wherein the first source/drain is connected to the first anode of the first OLED light-emitting unit; the second thin film transistor comprises a second active layer, a second gate and a second source/drain, the second source/drain is connected to the second anode of the second OLED light-emitting unit;
the first active layer and the second active layer, the first gate and the second gate, the first source/drain and the second source/drain are respectively arranged in a same layer.

9. The OLED display panel according to claim 1, wherein a metal reflective material is disposed on a part of region of a surface of the transparent base facing the display function layer, wherein the region of the surface of the transparent base disposed with the metal reflective material is the specular reflection area.

10. The OLED display panel according to claim 9, wherein the metal reflective material comprises one of molybdenum MO, aluminum Al, Al alloy, titanium Ti, Ti alloy, Ti/Al/Ti laminated structure, silver Ag, Ag alloy and laminated structures of indium tin oxide ITO/Ag/ITO, or a combination of at least two of molybdenum MO, aluminum Al, Al alloy, titanium Ti, Ti alloy, Ti/Al/Ti laminated structure, silver Ag, Ag alloy and laminated structures of indium tin oxide ITO/Ag/ITO.

11. A display device comprising the OLED display panel according to claim 1.

12. A method of forming a display panel, wherein the display panel is the display panel according to claim 1, and the method comprises:
forming a transparent base;
forming a specular function layer comprising a specular reflection area and a light-transmitting area on the transparent base;
forming a display function layer on the specular function layer;
the display function layer comprises a first pixel area and a second pixel area, the first pixel area is provided with a first OLED light-emitting unit, and the first OLED light-emitting unit is configured to emit light in a direction away from the transparent base; the second pixel area is provided with a second OLED light-emitting unit, the second OLED light-emitting unit is configured to emit light toward the transparent base, and the emitted light is able to pass through the light-transmitting area.

13. The method according to claim 12, wherein the forming the specular function layer comprising the specular reflection area and the light-transmitting area on the transparent base comprises:
depositing a metal reflective material on the transparent base;
patterning the metal reflective material to form a metal reflective material reserved area and a metal reflective material removed area, the metal reflective material reserved area is formed as the specular reflection area, and the metal reflective material removed area is formed as the light-transmitting area.

14. The method according to claim 12, wherein the first OLED light-emitting unit comprises a first anode, a first cathode and a first light-emitting layer between the first anode and the first cathode; the second OLED light-emitting unit comprises a second anode, a second cathode and a second light-emitting layer between the second anode and the second cathode, the forming the display function layer on the specular function layer comprises:
forming the first anode and the second anode through two patterning processes;
forming the first light-emitting layer and the second light-emitting layer through one evaporation process; and
forming the first cathode and the second cathode of the same material through the same vapor deposition process, or forming the first cathode and the second cathode of different materials through different vapor deposition processes.
